(19) United States
(12) Patent Application Publication
(10) Pub. No.: US 2005/0134323 A1
(43) Pub. Date: Jun. 23, 2005

(54) Single event transient filter for comparator

(75) Inventor: Timothy J. Nash, Riverview, FL (US)

Correspondence Address: SCHWEGMAN, LUNDBERG, WOESSNER & KLUTH, P.A., P.O. BOX 2938, MINNEAPOLIS, MN, 55402, US

(73) Assignee: Honeywell International Inc.

(21) Appl. No.: 10/745,124

(22) Filed: Dec. 23, 2003

(51) Int. Cl. H03D 13/00

(52) U.S. Cl. 327/40

(57) ABSTRACT

A R-C low pass filter is used in series with a Schmitt-trigger to form a mask for single event transients (SETs) in a comparator. Transients are masked to logic devices attached to an output of the comparator. A mask time is determined in part by the time constant of the R-C filter, and in part by hysteresis trip points of the Schmitt-trigger input. An inverter provides a stable logic level edge rate, which may have been affected by the R-C filter. In a further embodiment, a reverse biased diode is positioned to bypass the filter when the comparator output is low.

### FIELD OF THE INVENTION

The present invention relates to filters, and in particular to a single event transient filter for a comparator.

### BACKGROUND OF THE INVENTION

Some comparators are susceptible to single event transients (SETs) caused by solar flares and other radiation events. This can cause disruption in the comparator output level, which can cause problems in some circuits, such as power supply monitoring circuitry, which may inadvertently cause board-level or system-level resets.

Many of today's commercial integrated circuit (IC) devices and multi-chip modules (MCM) cannot be utilized in deep space and earth orbiting applications because of radiation induced transient pulses or other SETs. The commercial IC devices are developed and manufactured for the computer and mass market applications and cannot withstand the effects of radiation induced single event transients from either the natural space environment caused by solar flares, galactic cosmic radiation and the Van Allen electron and proton belts or man-made radiation induced events (neutrons and gamma radiation).

Common methods of preventing SETs from degrading performance are to design special radiation tolerant integrated circuits. One example uses source/drain masks to locally implant the minority carrier lifetime reducer (MCLR) before the source/drain dopants are implanted. This requires control of the die mask production process and production of the die. Another method implements system level monitoring and system or subsystem level shutdown of latched circuitry. A fuse is used in a further method to limit the current through the device. This has the disadvantage of being a non-recoverable latch-up unless the fuse is reset. In a further device, circuitry, integrated into the IC package provides protection through the automatic limiting and removal of power during an SEL event, allowing the device to reset from the event and then power-up of the device.

### SUMMARY OF THE INVENTION

A R-C low pass filter is used in series with a Schmitt-trigger to form a mask for single event transients (SETs) in a comparator. Transients are masked to logic devices attached to an output of the comparator. A mask time is determined in part by the time constant of the R-C filter, and in part by hysteresis trip points of the Schmitt-trigger input. A Schmitt-trigger inverter provides a stable logic level edge rate, which may have been affected by the R-C filter.

In a further embodiment, a reverse biased diode is positioned to bypass the filter when the comparator output is low.

### BRIEF DESCRIPTION OF THE DRAWINGS

FIG. 1 is a simplified circuit diagram of a single event transient filter with a comparator according to an embodiment of the invention.

FIG. 2 is a simplified circuit diagram of a further embodiment of the single event transient filter with a comparator according to an embodiment of the invention.

### DETAILED DESCRIPTION OF THE INVENTION

In the following description, reference is made to the accompanying drawings that form a part hereof, and in which is shown by way of illustration specific embodiments in which the invention may be practiced. These embodiments are described in sufficient detail to enable those skilled in the art to practice the invention, and it is to be understood that other embodiments may be utilized and that structural, logical and electrical changes may be made without departing from the scope of the present invention. The following description is, therefore, not to be taken in a limited sense, and the scope of the present invention is defined by the appended claims.

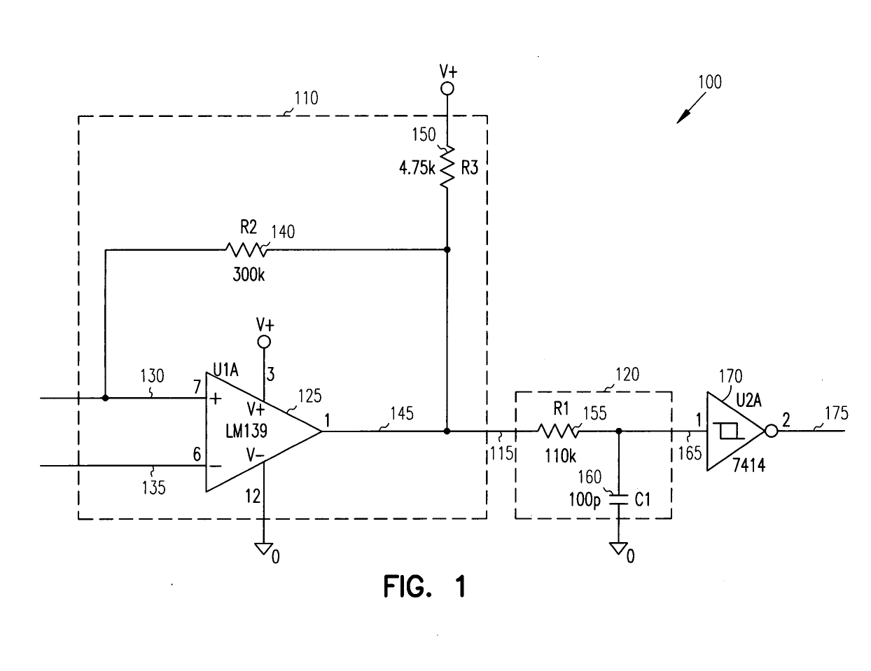

A circuit 100 in FIG. 1 comprises a comparator circuit 110 having an output 115 coupled to a R-C filter 120. The comparator circuit 110 has a comparator 125 with a first input 130 and a second input 135. Comparator 125 is a class of operational amplifier, such as one from the 139 family. (i.e. DSCC number 5962-96738—National Semiconductor's LM139A, DSCC number 5962-98613—Intersil's HS-139RH). Other types of comparators may also be used. A feedback resistor 140 is coupled between an output 145 of the comparator 125 and the first input 130. A bias resistor 150 is coupled between the output 145 and a bias voltage.

The low pass filter 120 comprises a resistor 155 coupled to a capacitor 160 to ground or other current sink. An input 165 of a logic circuit 170 is coupled between the resistor 155 and capacitor 160. The logic circuit 170 in one embodiment comprises a CMOS Schmitt-trigger inverter that provides a sharp edge output at a CMOS level.

Comparator circuit 110 is used in one embodiment to measure a difference in voltage between inputs 130 and 135. The comparator 125 may be susceptible to single-event transients (SETs) caused by exposure to heavy ion environments, such as found in space, such as in satellites or other high altitude devices. These transients show up on the output 115 of the comparator as a positive or negative going voltage spike. Low pass filter 120 is placed at the output of the comparator 115 and has a time constant set by the combination of capacitor 160 and the thevenin equivalent resistance formed by resistors 140, 150 and 155. The Schmitt-trigger inverter 170 is used on the output of the low pass filter to avoid slow rise and fall times inherent in R-C filters with very small rise and fall times. It also provides circuit 100 with nice clean CMOS edges.

In one embodiment, the R-C filter time constant is selected to accommodate a 3V transient of ˜3.4 us duration out of comparator 125, a LM139. The time constant is large enough to mask the transient, but small enough not to mask “real” problems (i.e. power supply glitches in the event that the power supply is being monitored). In further embodiments, different transients may be of concern, and the time constant may be smaller, or much larger if desired. Values for components in the figures are for one embodiment, and are not meant to limit the scope of the invention to those values.

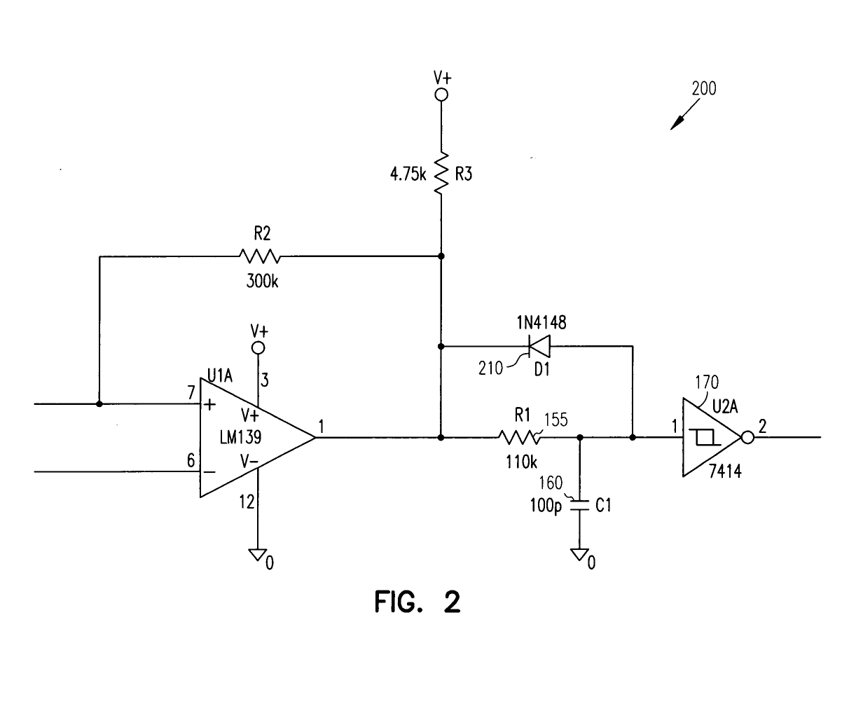

FIG. 2 shows an alternative circuit 200 that reduces delay caused in resetting the circuit. A reverse bias diode 210 is positioned across resistor 155, and provides a bypass of the R-C filter 120 when the comparator output 115 transistions from high to low. It forces a board reset, and a high output value at 175.

By using an R-C low-pass filter in series with a Schmitt-trigger inverter, transients are masked to logic devices attached to the output of the comparator. The mask time is determined in part by the time constant of the R-C filter, and in part by the hysteresis trip-points of the Schmitt-trigger 170 input 165. The inverter portion of the Schmitt-trigger provides a stable logic level edge rate.

1. A circuit comprising:
a comparator having two inputs and a comparator output;
an RC delay circuit coupled to the comparator output;
a feedback resistor coupled between the comparator output and one of the inputs; and
a logic device coupled to an output of the RC delay circuit to provide a logic device output having clean edges, wherein the RC delay circuit has an RC time constant sufficient to prevent single event transients from adversely affecting the logic device output.

2. The circuit of claim 1 wherein the logic device comprises a Schmitt-trigger inverter that provides clean CMOS edge output.

3. The circuit of claim 1 wherein the resistance of the first resistor contributes to the RC time constant of the RC delay circuit.

4. The circuit of claim 3 wherein the comparator has a second resistor coupled between the comparator output and a voltage supply, wherein the resistance of the second resistor contributes to the RC time constant of the RC delay circuit.

5. The circuit of claim 4 wherein the RC delay circuit comprises a third resistor and a capacitor coupled to ground, and between the third resistor and an input of the logic device, wherein the RC time constant is a function of a thevenin resistance of the feedback, second and third resistors.

6. A circuit comprising:
a comparator having two inputs and a comparator output;
an RC delay circuit coupled to the comparator output;
a bypass coupled to the RC delay circuit; and
a logic device coupled to an output of the RC delay circuit to provide a logic device output having clean edges, wherein the RC delay circuit has an RC time constant sufficient to prevent single event transients from adversely affecting the desired logic device output.

7. The circuit of claim 6, wherein the bypass comprises a reverse biased diode.

8. The circuit of claim 7 wherein the reverse biased diode is coupled across a resistor of the RC delay circuit.

9. A device that reduces effects of single event transients on a comparator output, the device comprising:
means for comparing inputs to provide a comparator output;
means for providing the comparator output to a RC delay circuit having an RC time constant sufficient to prevent single event transients from adversely affecting the desired logic device output; and
means for inverting an output of the RC delay circuit to provide an output having sharp CMOS edges.

10. A method of reducing effects of single event transients on a comparator output, the method comprising:
comparing inputs to provide a comparator output;
providing the comparator output to a RC delay circuit having an RC time constant sufficient to prevent single event transients from adversely affecting the desired logic device output; and
inverting an output of the RC delay circuit to provide an output having sharp CMOS edges.

11. The method of claim 10 and further comprising bypassing the RC delay circuit when the comparator output is low.
